(19) United States
(12) Patent Application Publication
(10) Pub. No.: US 2026/0255939 A1
(43) Pub. Date: Aug. 27, 2026

(54) SUB-LITHOGRAPHICALLY SEPARATED INTERCONNECT STRUCTURES AND METHODS OF MAKING THE SAME

(71) Applicant: Sandisk Technologies, Inc., Milpitas, CA (US)

(72) Inventors: Hiroshi NAKATSUJI, Yokkaichi (JP); Kosuke TANAKA, Yokkaichi (JP); Kiyokazu SHISHIDO, Yokkaichi (JP); Eiichi FUJIKURA, Yokkaichi (JP)

(21) Appl. No.: 19/065,306

(22) Filed: Feb. 27, 2025

(51) Int. Cl. H01L 21/768; H01L 21/027; H01L 21/311; H01L 23/522; H01L 23/528; H10D 30/63; H10D 62/10; H10D 84/03; H10D 84/83

(52) U.S. Cl. CPC H10W 20/056; H10D 30/63; H10D 62/124; H10D 84/837; H10P 50/283; H10P 50/73; H10P 76/2041; H10W 20/033; H10W 20/076; H10W 20/089; H10W 20/42; H10W 20/43; H10D 84/038; H10W 20/435

(57) ABSTRACT

Via cavities can be formed through a contact-level dielectric layer by performing an anisotropic via etch process that employs a hard mask layer containing hard mask openings as a via etch mask. Sacrificial spacer liners can be formed in peripheral regions of the via cavities. The hard mask layer can be patterned into at least one discrete hard mask plate. Integrated line-and-via cavities can be formed by performing an anisotropic line etch process that employs a combination of a patterned photoresist layer and the at least one discrete hard mask plate as a line etch mask. The patterned photoresist layer, the at least one discrete hard mask plate, and the sacrificial spacer liners can be removed. Metal interconnect structures can be formed within the integrated line-and-via cavities.

### FIELD

The present disclosure generally relates to semiconductor devices, and particularly to sub-lithographically separated interconnect structures for transistors and methods of manufacturing the same.

### BACKGROUND

The minimum metal line spacing between a neighboring pair of metal lines is normally limited by the lithographic resolution of an exposure tool that is employed to form the lithographic pattern for the metal lines. Use of an exposure tool having a small critical dimension is expensive. Thus, a method of forming metal line patterns with a sub-lithographic lateral spacing is desired.

### SUMMARY

According to an aspect of the present disclosure, a method of forming a device structure comprises forming a contact-level dielectric layer over a semiconductor device; forming a hard mask layer containing hard mask openings over top surface of the contact-level dielectric layer; forming via cavities through the contact-level dielectric layer by performing an anisotropic via etch process that employs a hard mask layer as a via etch mask; forming sacrificial spacer liners in peripheral regions of the via cavities; patterning the hard mask layer into at least one discrete hard mask plate; forming integrated line-and-via cavities by performing an anisotropic line etch process that employs a combination of a patterned photoresist layer and the at least one discrete hard mask plate as a line etch mask, wherein the integrated line-and-via cavities include all volumes of the via cavities and volumes of line cavities that are formed by removal of upper portions of the contact-level dielectric layer by the anisotropic line etch process; removing the patterned photoresist layer, the at least one discrete hard mask plate, and the sacrificial spacer liners, such that volumes of the integrated line-and-via cavities increase by volumes of the removed sacrificial spacer liners; and forming metal interconnect structures within the integrated line-and-via cavities.

According to another aspect of the present disclosure, a field effect transistor comprises a semiconductor source region; a semiconductor drain region; a semiconductor channel region located between the semiconductor source region and the semiconductor drain region; a gate dielectric layer located over the semiconductor channel region; and a gate electrode located over the gate dielectric layer. A contact-level dielectric layer is located over the gate electrode. A drain integrated line-and-via structure is embedded in the contact-level dielectric layer, and comprises a first via portion that contacts the semiconductor drain region and a first line portion overlying the first via portion. A gate integrated line-and-via structure is also embedded in the contact-level dielectric layer, and comprises a second via portion that contacts the gate electrode and a second line portion overlying the second via portion. The first line portion comprises: an elongated line portion that laterally extends along a first horizontal direction and is laterally offset from the first and second via portions along a second horizontal direction that is perpendicular to the first horizontal direction; a stub portion that overlies the first via portion and having a first convex sidewall that extends substantially along the second horizontal direction; and a connection line portion that laterally extends along the second horizontal direction and connecting the stub portion and the elongated line portion. The second line portion comprises a second convex sidewall that extends substantially along the second horizontal direction and faces the first convex sidewall; and the first and the second line portions are wider at their top than at their bottom.

### BRIEF DESCRIPTION OF THE DRAWINGS

For all figures between FIGS. 1A and 18D, which are labeled with a combination of a figure numeral and a letter figure suffix, each figure with a figure label including a letter figure suffix of “A” is a vertical cross-sectional view of an exemplary structure; each figure with a figure label including a letter figure suffix of “B” is a top-down view of the exemplary structure illustrated in the figure with the same figure numeral and the letter figure suffix of “A”; each figure with a figure label including a letter figure suffix of “C” is a vertical cross-sectional view along the vertical plane C-C′ within the figures with the same figure numeral and the letter figure suffix of “A” or “B”; and each figure with a figure label including a letter figure suffix of “D” is a vertical cross-sectional view along the vertical plane D-D′ within the figures with the same figure numeral and the letter figure suffix of “A” or “B”. The vertical cross-sectional plane D-D′ may have a lateral step as illustrated in figures with the letter figure suffix of “A.”

FIGS. 1A, 1B, 1C, and 1D are various views of an exemplary structure after formation of a pair of field effect transistors sharing a common drain region according to an embodiment of the present disclosure.

FIGS. 2A, 2B, 2C, and 2D are various views of the exemplary structure after formation of a dielectric capping liner and a contact-level dielectric layer according to an embodiment of the present disclosure.

FIGS. 3A, 3B, 3C, and 3D are various views of the exemplary structure after formation of a hard mask layer according to an embodiment of the present disclosure.

FIGS. 4A, 4B, 4C, and 4D are various views of the exemplary structure after formation of via cavities according to an embodiment of the present disclosure.

FIGS. 5A, 5B, 5C, and 5D are various views of the exemplary structure after deposition of a sacrificial spacer liner layer according to an embodiment of the present disclosure.

FIGS. 6A, 6B, 6C, and 6D are various views of the exemplary structure after deposition of a sacrificial etch stop material layer according to an embodiment of the present disclosure.

FIGS. 7A, 7B, 7C, and 7D are various views of the exemplary structure after formation of sacrificial etch stop pillars according to an embodiment of the present disclosure.

FIGS. 8A, 8B, 8C, and 8D are various views of the exemplary structure after formation of sacrificial spacer liners according to an embodiment of the present disclosure.

FIGS. 9A, 9B, 9C, and 9D are various views of the exemplary structure after removal of the sacrificial etch stop pillars according to an embodiment of the present disclosure.

FIGS. 10A, 10B, 10C, and 10D are various views of the exemplary structure after performing a pull back process on the hard mask layer according to an embodiment of the present disclosure.

FIGS. 11A, 11B, 11C, and 11D are various views of the exemplary structure after formation of a sacrificial planarization material layer and an etch mask material portion according to an embodiment of the present disclosure.

FIGS. 12A, 12B, 12C, and 12D are various views of the exemplary structure after patterning the sacrificial planarization material layer and the hard mask layer employing the etch mask material portion as an etch mask and after removal of the sacrificial planarization material layer according to an embodiment of the present disclosure.

FIGS. 13A, 13B, 13C, and 13D are various views of the exemplary structure after formation of a self-planarizing material layer and a patterned photoresist layer according to an embodiment of the present disclosure.

FIGS. 14A, 14B, 14C, and 14D are various views of the exemplary structure after formation of line cavities according to an embodiment of the present disclosure.

FIGS. 15A, 15B, 15C, and 15D are various views of the exemplary structure after removal of hard mask plates according to an embodiment of the present disclosure.

FIGS. 16A, 16B, 16C, and 16D are various views of the exemplary structure after removal of sacrificial spacer liners according to an embodiment of the present disclosure.

FIGS. 17A, 17B, 17C, and 17D are various views of the exemplary structure after deposition of a metallic barrier liner layer and a metallic fill material layer according to an embodiment of the present disclosure.

FIGS. 18A, 18B, 18C, and 18D are various views of the exemplary structure after formation of metal interconnect structures according to an embodiment of the present disclosure.

### DETAILED DESCRIPTION

Embodiments of the present disclosure are directed to sub-lithographically separated interconnect structures for field effect transistors and methods of manufacturing the same. The embodiments of the disclosure can be employed to form various semiconductor structures which contain the field effect transistors, such as CMOS devices for driver circuits of a non-volatile memory device, in which the memory cells are located over the CMOS devices.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous contiguous structure that has a thickness less than the thickness of the contiguous structure. For example, a layer may be located between any pair of horizontal planes between, or at, a top surface and a bottom surface of the contiguous structure. A layer may extend horizontally, vertically, and/or along a tapered surface. A substrate may be a layer, may include one or more layers therein, and/or may have one or more layer thereupon, thereabove, and/or therebelow.

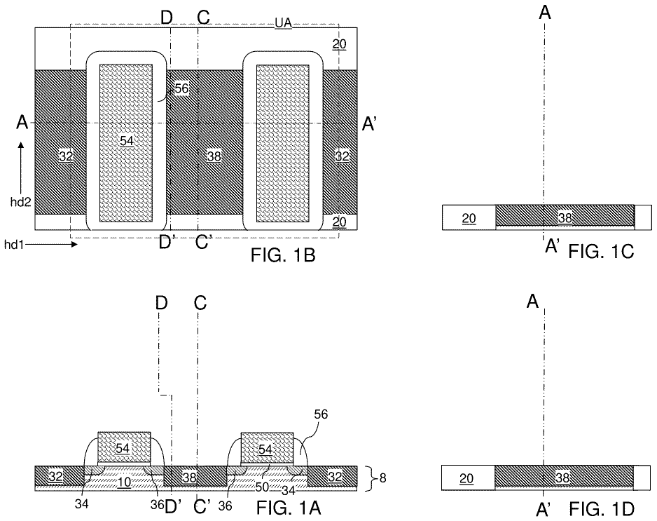

Referring to FIG. 1A-1D, an exemplary semiconductor structure according to an embodiment of the present disclosure is illustrated. The exemplary semiconductor structure comprises a substrate 8 including a semiconductor material layer 10. The substrate 8 may comprise a single crystalline semiconductor substrate, such as a single crystalline silicon wafer, or a silicon on insulator substrate. The semiconductor material layer 10 can include at least one elemental semiconductor material, at least one III-V compound semiconductor material, at least one II-VI compound semiconductor material, at least one organic semiconductor material, or other semiconductor materials known in the art. The semiconductor material layer 10 can be a single crystalline semiconductor material layer. In one embodiment, the semiconductor material layer 10 can be a single crystalline silicon layer.

The semiconductor material layer 10 can a doped well in an upper portion of a semiconductor substrate 8 or an epitaxial semiconductor layer located over a top surface of a substrate 8. The semiconductor material layer 10 can be intrinsic, p-doped, or n-doped. If it is p-doped or n-doped, the semiconductor material layer 10 can have a dopant concentration in a range from 1.0×10¹⁴/cm³ to 1.0×10¹⁸/cm³, although lesser and greater dopant concentrations can also be employed.

As used herein, a “semiconductor material” refers to a material having electrical conductivity in the range from 1.0×10⁻⁶ S/cm to 1.0×10⁵ S/cm, and is capable of producing a doped material having electrical resistivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁶ S/cm. All measurements for electrical conductivities are made at the standard condition.

Semiconductor devices (e.g., field effect transistors) having electrically conductive nodes (e.g., heavily-doped semiconductor source and drain regions and/or conductive gate electrodes) can be formed on the semiconductor material layer 10. The semiconductor devices may comprise heavily-doped semiconductor material portions (e.g., source and drain regions) that are subsequently contacted by a respective contact via structure. In one embodiment, the semiconductor devices comprise field effect transistors formed on the semiconductor material layer 10 as the. Shallow trench isolation structures 20 can be formed to provide electrical isolation among devices.

In an illustrative example, the semiconductor devices may comprise a two-dimensional periodic array of sense amplifiers including a pair of field effect transistors within a unit cell, i.e., a repetition unit that is repeated within the two-dimensional periodic array. In this case, multiple instances of the repetition unit can be repeated as the two-dimensional periodic array. Each repetition unit can be formed within a respective unit area UA. The region illustrated in FIG. 1A-1D corresponds to the region of a single instance of the repetition unit. The multiple instances of the repetition unit may be repeated along a first horizontal direction hd1 and along a second horizontal direction hd2 such that neighboring instances of the repetition unit along the first horizontal direction hd1 include mirror images of each other. In other words, upon sequentially numbering the instances of the repetition units along the first horizontal direction with consecutive integers, odd-numbered instances of the repetition unit may have a mirror image of the even-numbered instances of the repetition unit. Portions of the shallow trench isolation structures 20 may merge along the first horizontal direction hd1 to provide strips of shallow trench isolation structures 20 that laterally extend along the first horizontal direction hd1.

Each instance of the repetition unit may comprise a first gate stack (50, 54) including a first gate dielectric 50 and a first gate electrode 54, a second gate stack (50, 54) including a second gate dielectric 50 and a second gate electrode 54, a first source region 32, a second source region 32, a common drain region 38. Dielectric gate spacers 56 may be formed around each gate stack (50, 54). A source extension region 34 may be formed adjacent to each source region 32 underneath a respective dielectric gate spacer 56. A drain extension region 36 may be formed adjacent to the common drain region 38 underneath a respective dielectric gate spacer 56.

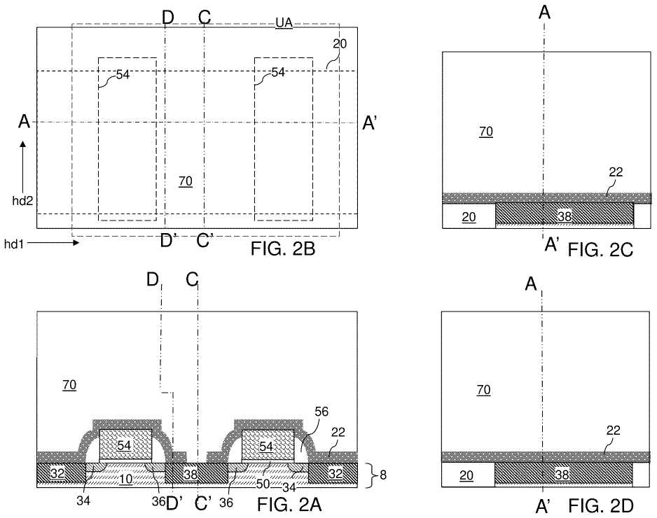

Referring to FIGS. 2A, 2B, 2C, and 2D, a dielectric capping liner 22 can be deposited over the semiconductor devices. The dielectric capping liner 22 comprises a dielectric barrier material such as silicon nitride, a dielectric metal oxide, silicon carbide nitride, and/or silicon oxide. The dielectric capping liner 22 may have a thickness in a range from 5 nm to 60 nm, although lesser or greater thicknesses may also be employed.

A contact-level dielectric layer 70 can be deposited over the dielectric capping liner 22. The contact-level dielectric layer 70 may comprise a planarizable dielectric material or a self-planarizing dielectric material. For example, the contact-level dielectric layer 70 may comprise undoped silicate glass (i.e., silicon oxide), a doped silicate glass, or organosilicate glass. The contact-level dielectric layer 70 may be formed by chemical vapor deposition or by spin coating. Optionally, a chemical mechanical polishing process may be performed to planarize the top surface of the contact-level dielectric layer 70. The vertical distance between the top surface of the contact-level dielectric layer 70 and the topmost surface segments of the dielectric capping liner 22 may be in a range from 150 nm to 1,000 nm, such as from 200 nm to 600 nm, although lesser or greater vertical distances may also be employed.

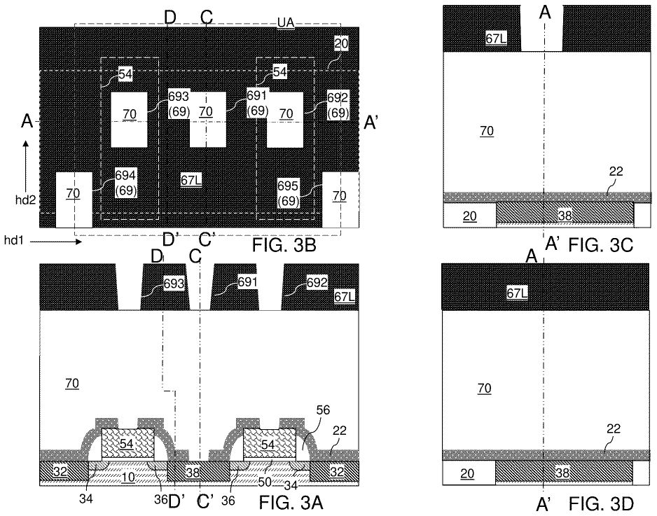

Referring to FIGS. 3A, 3B, 3C, and 3D, a hard mask layer 67L can be formed on the top surface of the contact-level dielectric layer 70. The hard mask layer 67L comprises a hard mask material such as silicon nitride or a conductive metallic nitride material (such as TiN, TaN, WN, or MoN). The thickness of the hard mask layer 67L may be in a range from 50 nm to 300 nm, although lesser or greater thicknesses may also be employed. The hard mask layer 67L may be formed by depositing a blanket hard mask material layer, by applying and patterning a photoresist layer over the blanket hard mask material layer, and by transferring the pattern of openings in the patterned photoresist layer through the blanket hard mask material layer.

The hard mask layer 67L comprises openings therethrough, which are herein referred to as hard mask openings 69. In one embodiment, each unit area UA of repetition may comprise a first hard mask opening 691 that is formed over the area of a drain region 38, a second hard mask opening 692 that is formed over the area of a first gate electrode 54, a third hard mask opening 693 that is formed over the area of a second gate electrode 54, one half of a fourth hard mask opening 694 that is formed over the area of a first source region 32 (which may be shared with a field effect transistor in a first neighboring unit area UA), and one half of a fifth hard mask opening 695 that is formed over the area of a second source region 32 (which may be shared with a field effect transistor in a second neighboring unit area UA).

In one embodiment, the first hard mask opening 691, the second hard mask opening 692, and the third hard mask opening 693 may be aligned and spaced from each other along the first horizontal direction hd1, and may have a same lateral extent along the second horizontal direction hd2. In this case, the lateral extent of each of the hard mask opening 691, the second hard mask opening 692, and the third hard mask opening 693 may be the same as the maximum lateral extent of via cavities to be subsequently formed in the contact-level dielectric layer 70, and as such, is herein referred to as a via width VW. The fourth hard mask opening 694 and the fifth hard mask opening 695 may be laterally spaced along the first horizontal direction, and may have a same lateral extent along the second horizontal direction hd2. In one embodiment, the lateral extent of each of the fourth hard mask opening 694 and the fifth hard mask opening 695 may be the same as the via width VW. In one embodiment, the fourth hard mask opening 694 and the fifth hard mask opening 695 may be laterally offset from the row of the first hard mask opening 691, the second hard mask opening 692, and the third hard mask opening 693 along the second horizontal direction hd2 by a pitch of metal lines to be subsequently formed. The lateral offset is measured by a center-to-center distance along the second horizontal direction hd2. The pitch of the metal lines to be subsequently formed is measured along the second horizontal direction hd2.

Each of the hard mask openings 69 has a respective peripheral edge, which can be the bottom edge of the sidewall(s) of the respective hard mask opening 69 that forms a closed shape in a top-down view. In the illustrative example shown in FIG. 3B, each of the peripheral edges of the hard mask openings 69 is a rectangle. Specifically, the first hard mask opening 691 may have a first peripheral edge, the second hard mask opening 692 may have a second peripheral edge, the third hard mask opening 693 may have a third peripheral edge, the fourth hard mask opening 694 may have a fourth peripheral edge, and the fifth hard mask opening 695 may have a fifth peripheral edge.

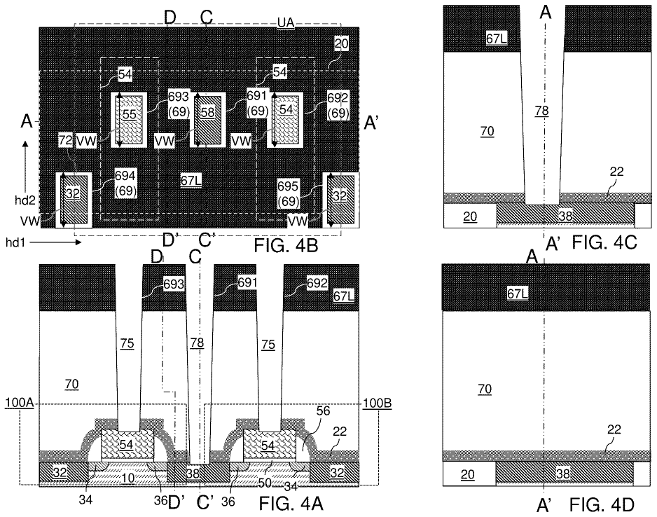

Referring to FIGS. 4A, 4B, 4C, and 4D, an anisotropic etch process can be performed to etch unmasked portions of the contact-level dielectric layer 70 and the dielectric capping liner 22. The anisotropic etch process may comprise a first anisotropic etch step that etches the material of the contact-level dielectric layer 70 selectively to the material of the dielectric capping liner 22 employing the hard mask layer 67L as a via etch mask. Further, the anisotropic etch process may comprise a subsequent second anisotropic etch step that etches the material of the dielectric capping liner 22 selectively to the materials of the semiconductor material layer 10 and the gate electrodes 54 employing the hard mask layer 67L as a via etch mask. Via cavities (78, 75, 72) are formed through the contact-level dielectric layer 70 and the dielectric capping liner 22 such that top surfaces of conductive structures of electrical nodes (e.g., drain region 38, the gate electrodes 54, and the source regions 32) of the underlying semiconductor devices (i.e., transistors) are physically exposed at the bottom of the respective via cavities (78, 75, 72).

The via cavities (78, 75, 72) comprise a first via cavity (such as a drain contact via cavity 78) that is formed underneath the first hard mask opening 691 and vertically extending to a top surface of a drain region 38; a second via cavity (such as a first gate contact via cavity 75) that is formed underneath the second hard mask opening 692 and vertically extending to a top surface of a first gate electrode 54; a third via cavity (such as a second gate contact via cavity 75) that is formed underneath the third hard mask opening 693 and vertically extending to a top surface of a second gate electrode 54; a fourth via cavity (such as a first source contact via cavity 72) that is formed underneath the fourth hard mask opening 694 and vertically extending to a top surface of a first source region 32; and a fifth via cavity (such as a second source contact via cavity 72) that is formed underneath the fifth hard mask opening 695 and vertically extending to a top surface of a second source region 32.

In one embodiment, the semiconductor devices in a unit area UA comprise a pair of field effect transistors (100A, 110B) having a common drain region 38. The first field effect transistor 100A include a first gate electrode 54 and a first source region 32. The second field effect transistor 100B includes a second gate electrode 54 and a second source region 32. The first via cavity (such as a drain contact via cavity 78) vertically extends down to a top surface segment of the common drain region 38; the second via cavity (such as a gate contact via cavity 75) vertically extends down to a top surface segment of the first gate electrode 54; the third via cavity (such as an additional gate contact via cavity 75) vertically extends down to a top surface segment of the second gate electrode 54; the fourth via cavity (such as a first source contact via cavity 72) vertically extends to a top surface segment of the first source region 32; and the fifth via cavity (such as a second source contact via cavity 72) vertically extends to a top surface segment of the second source region 32.

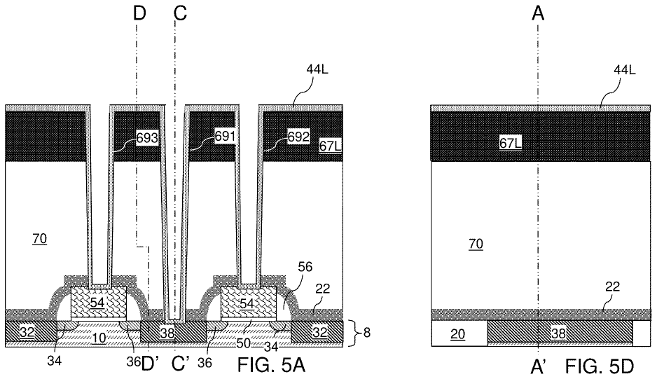

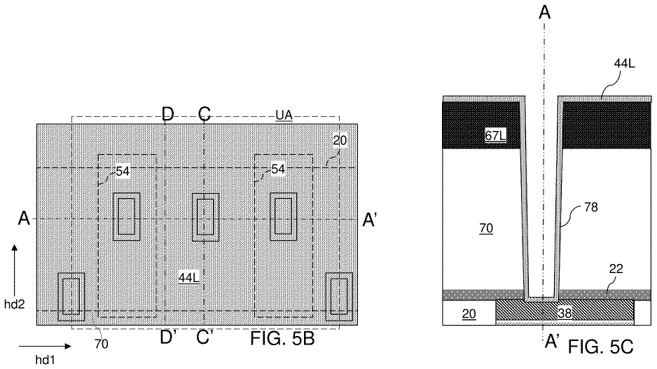

Referring to FIGS. 5A, 5B, 5C, and 5D, a sacrificial spacer liner layer 44L can be deposited in peripheral regions of the via cavities (78, 75, 72) and over the hard mask layer 67L. The sacrificial spacer liner layer 44L comprises a first sacrificial material. In one embodiment, the first sacrificial material may comprise a material that can be subsequently removed selectively to the material of the dielectric capping liner 22. In one embodiment, the first sacrificial material of the sacrificial spacer liner layer 44L may comprise silicon oxide, such as a low temperature silicon oxide, a doped silicate glass, or organosilicate glass having a higher etch rate in dilute hydrofluoric acid than the material of the contact-level dielectric layer 70. The sacrificial spacer liner layer 44L can be conformally deposited by a conformal deposition process such as a chemical vapor deposition process. The thickness of the sacrificial spacer liner layer 44L may be in a range from 1 nm to 20 nm, such as from 2 nm to 10 nm, although lesser or greater thicknesses may also be employed.

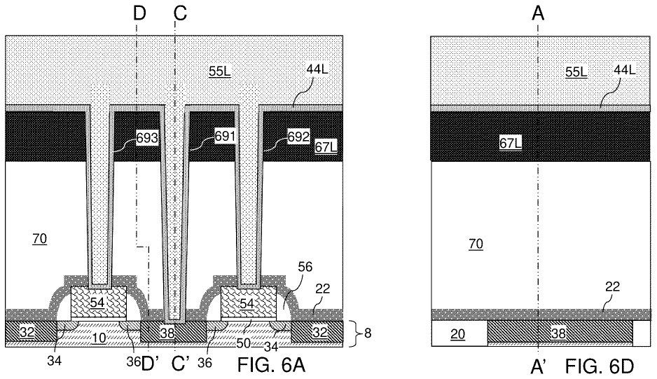

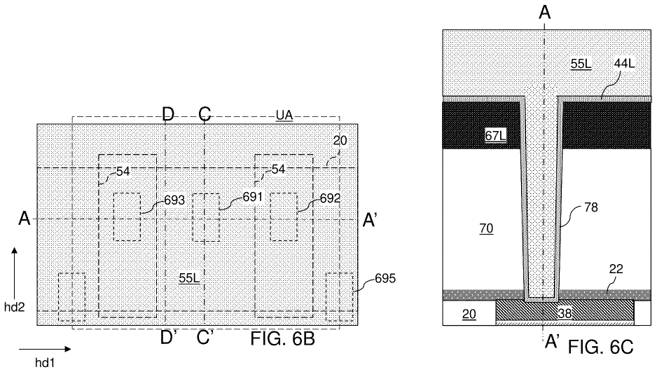

Referring to FIGS. 6A, 6B, 6C, and 6D, a sacrificial etch stop material layer 55L can be applied over the sacrificial spacer liner layer 44L. The sacrificial etch stop material layer 55L may comprise a self-planarizing material that may be spin-coated over the sacrificial spacer liner layer 44L. For example, the sacrificial etch stop material layer 55L may comprise a photoresist, such as a novolac-based resin with a photoactive compound, poly(methyl methacrylate) (PMMA), or a crosslinkable spin-on-glass material. Alternatively, the sacrificial etch stop material layer 55L may comprise a polyimide or a fluorinated polymer. Yet alternatively, the sacrificial etch stop material layer 55L may comprise a carbon-based material, such as amorphous carbon or diamond-like carbon. The thickness of the horizontally-extending portion of the sacrificial etch stop material layer 55L overlying the hard mask layer 67L may be in a range from 50 nm to 500 nm, although lesser or greater thicknesses may also be employed.

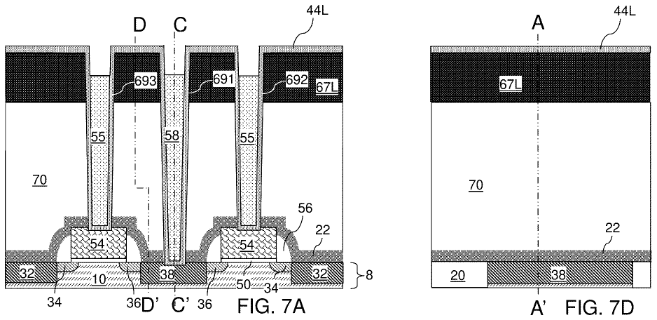

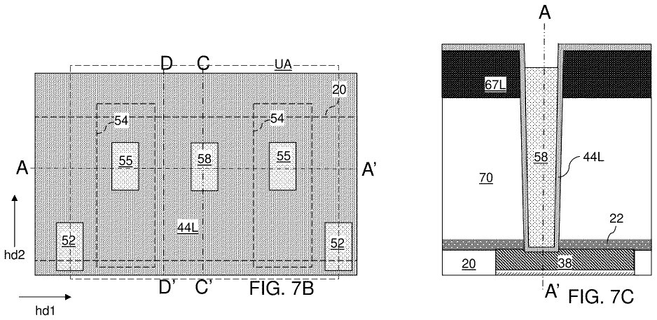

Referring to FIGS. 7A, 7B, 7C, and 7D, a recess etch process can be performed to remove the horizontally-extending portion of the sacrificial etch stop material layer 55L that overlies the hard mask layer 67L. The duration of the recess etch process can be selected such that each remaining portion of the material of the sacrificial etch stop material layer 55L located within a respective via cavity (78, 75, 72) has a respective top surface located between a horizontal plane including the bottom surface of the hard mask layer 67L and a horizontal plane including the top surface of the hard mask layer 67L. Each remaining portion of the sacrificial etch stop material layer 55L located in a respective via cavity (78, 75, 72) constitutes a sacrificial etch stop pillars (58, 55, 52). Generally, the sacrificial etch stop pillars (58, 55, 52) can be formed in center regions of the respective via cavities (78, 75, 72) by depositing and vertically recessing a sacrificial etch stop material.

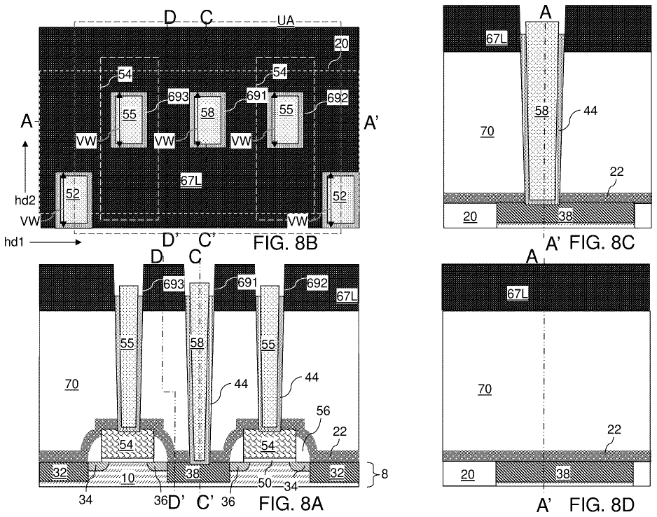

Referring to FIGS. 8A, 8B, 8C, and 8D, a selective etch process can be performed to etch unmasked portions of the material of the sacrificial spacer liner layer 44L selectively to the material of the sacrificial etch stop pillars (58, 55, 52). Specifically, portions of the sacrificial spacer liner layer 44L that are not masked by the sacrificial etch stop pillars (58, 55, 52) can be removed by the selective etch process. For example, if the sacrificial spacer liner layer 44L comprises a low temperature silicon oxide, a doped silicate glass, or organosilicate glass, the selective etch process may comprise a wet etch process employing dilute hydrofluoric acid. Each remaining portion of the sacrificial spacer liner layer 44L constitutes a sacrificial spacer liner 44. The sacrificial spacer liners 44 are formed in peripheral regions of the via cavities (78, 75, 72), and may have a respective annular top surface located between the horizontal plane including the bottom surface of the hard mask layer 67L and the horizontal plane including the top surface of the hard mask layer 67L.

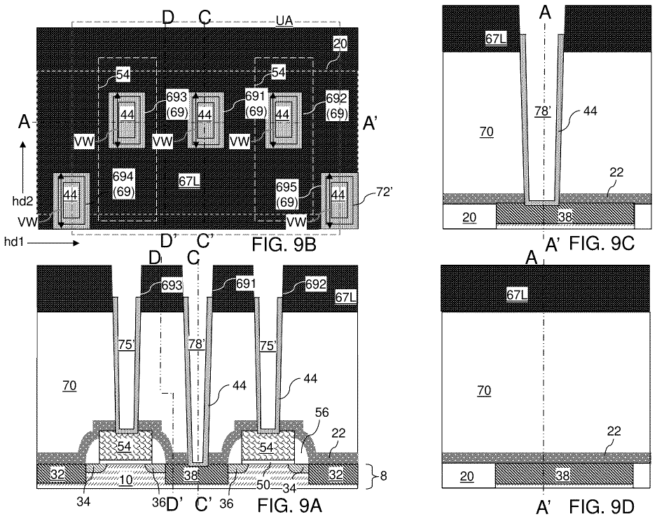

Referring to FIGS. 9A, 9B, 9C, and 9D, the sacrificial etch stop pillars (58, 55, 52) can be removed without removing the hard mask layer 67L or the sacrificial spacer liners 44. For example, if the sacrificial etch stop pillars 55 comprise a polymer material or a carbon-based material, an ashing process may be performed to remove the sacrificial etch stop pillars (58, 55, 52). A first void 78′ may be provided in a center region within the first via cavity, i.e., the drain contact via cavity 78. A second void 75′ may be provided in a center region within the second via cavity, i.e., the first gate contact via cavity 75. A third void 75′ may be provided in a center region within the third via cavity, i.e., the second gate contact via cavity 75. A fourth void 72′ may be formed in a center region within the fourth via cavity, i.e., the first source contact via cavity 72. A fifth void 72′ may be formed in a center region within the fifth via cavity, i.e., the second source contact via cavity 72.

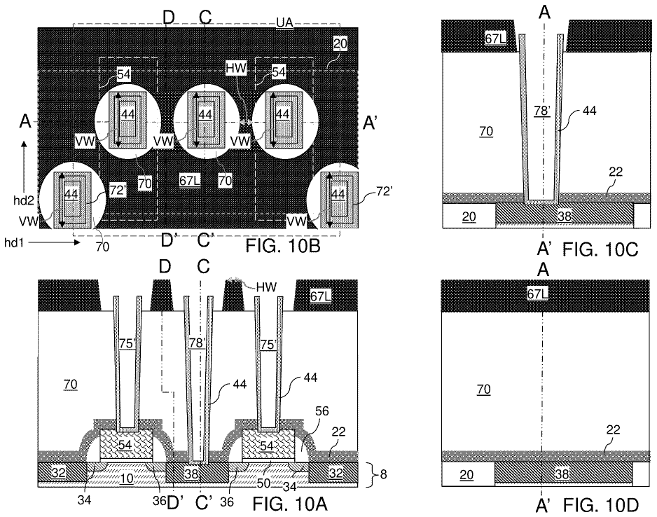

Referring to FIGS. 10A, 10B, 10C, and 10D, a pull back process can be performed on the hard mask layer 67L to isotropically laterally recess the sidewalls of the various hard mask openings 69. The pull back process may comprise a selective isotropic etch process that isotropically recesses the material of the hard mask layer 67L selectively to the materials of the contact-level dielectric layer 70 and the sacrificial spacer liners 44. In an illustrative example, if the hard mask layer 67L comprises silicon nitride, a wet etch process employing hot phosphoric acid may be performed to isotropically recess the hard mask layer 67L.

The duration of the selective isotropic etch process can be selected to be less than one half of the lateral distance between nearest neighboring pairs of hard mask openings 69 as formed at the processing steps of FIG. 3A-3D. Generally, the duration of the selective isotropic etch process can be selected such that the difference between nearest neighboring pairs of hard mask openings 69 as formed at the processing steps of FIG. 3A-3D and twice the lateral etch distance of the selective isotropic etch process for the material of the hard mask layer 67L is a sub-lithographic dimension. As used herein, a sub-lithographic dimension refers to a spatial dimension that is smaller than the minimum resolvable feature size or critical dimension achievable by a given lithographic patterning process. For example, if the smallest resolvable dimension (such as the minimum spacing between two neighboring features) for a particular lithographic process is 20 nm, then any dimension smaller than 20 nm for a comparable feature type (such as the spacing between neighboring line patterns) is defined as a sub-lithographic dimension. Thus, the duration of the selective isotropic etch process can be selected to generate at least one sub-lithographic dimension within the geometrical features of the remaining portion of the hard mask layer 67L. In other words, the horizontal width, HW, of the portion of the hard mask layer 67L between two adjacent openings 69 along the first horizontal direction hd1 is a sub-lithographic width.

Specifically, the bottom periphery of each hard mask opening 69 through the hard mask layer 67L may shift outward during the selective isotropic etch process. As discussed above, the hard mask layer 67L as formed at the processing steps of FIG. 3A-3D may have a first hard mask opening 691, a second hard mask opening 692, a third hard mask opening 693, a fourth hard mask opening 694, and a fifth hard mask opening 695. The first hard mask opening 691 may have a first peripheral edge, the second hard mask opening 692 may have a second peripheral edge, the third hard mask opening 693 may have a third peripheral edge, the fourth hard mask opening 694 may have a fourth peripheral edge, and the fifth hard mask opening 695 may have a fifth peripheral edge. All peripheral edges can be located within the horizontal plane including the bottom surface of the hard mask layer 67L.

The selective isotropic etch process expands outward each of the first peripheral edge, the second peripheral edge, the third peripheral edge, the fourth peripheral edge, and the fifth peripheral edge. In one embodiment, the first hard mask opening 691 may be located between the second hard mask opening 692 and the third hard mask opening 693, and the selective isotropic etch process may laterally expand the first peripheral edge, the second peripheral edge, and the third peripheral edge such that the lateral distance HW between the first peripheral edge and the second peripheral edge is a first sub-lithographic dimension after the selective isotropic etch process, and the lateral distance HW between the first peripheral edge and the second peripheral edge is a second sub-lithographic dimension after the selective isotropic etch process. In an illustrative example, the first sub-lithographic dimension and the second sub-lithographic dimension may be in a range from 10% to 90% of the critical dimension (i.e., the minimum printable dimension achievable through a single lithographic exposure) for the lithographic patterning process to be subsequently employed to pattern metal lines. In an illustrative example, if the lithographic patterning process to be subsequently employed to pattern metal lines has a critical dimension of 20 nm, the first sub-lithographic dimension and the second sub-lithographic dimension may be in a range from 2 nm to 18 nm.

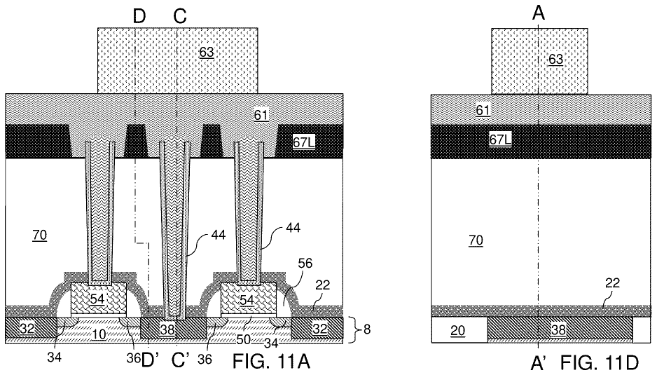

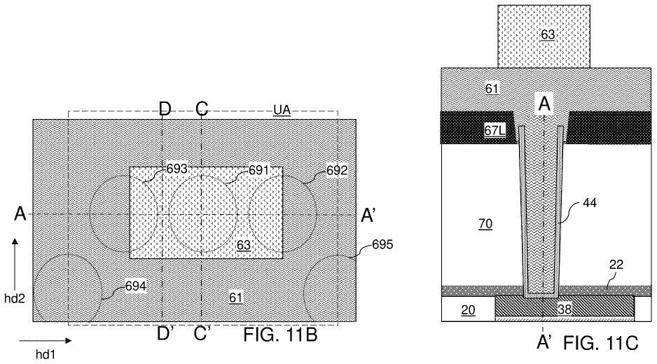

Referring to FIG. 11A-11D, a sacrificial planarization material layer 61 can be applied over the sacrificial spacer liners 44, the contact-level dielectric layer 70, and the hard mask layer 67L. The sacrificial planarization material layer 61 comprises a bottom anti-reflective coating (BARC) material or a planarizing underlayer material such as spin-on-carbon (SOC) or an organic planarization layer (OPL). The sacrificial planarization material layer 61 can be formed employing a self-planarization process, such as spin coating. Thus, the top surface of the sacrificial planarization material layer 61 can be planar or substantially planar, and reduces surface topography relative to the top surfaces of underlying structures. The sacrificial planarization material layer 61 improves the pattern fidelity in a photoresist layer that is formed thereabove.

A patterned etch mask material portion 63 (such as a patterned photoresist material portion) can be formed over the sacrificial planarization material layer 61 in each unit area UA. The patterned etch mask material portion 63 covers segments of the first peripheral edge of the first hard mask opening 691 that generally extend along the second horizontal direction hd2, a segment of the second peripheral edge of the second hard mask opening 692 that is proximal to the first hard mask opening 691, and a segment of the third peripheral edge of the third hard mask opening 693 that is proximal to the first hard mask opening 691.

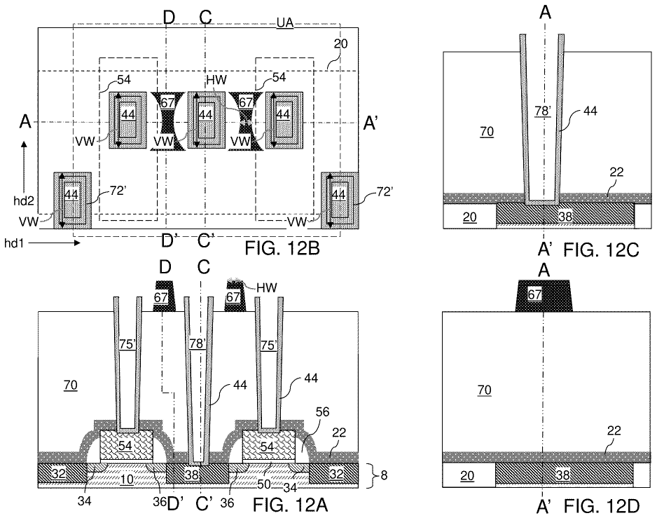

Referring to FIGS. 12A, 12B, 12C, and 12D, portions of the hard mask layer 67L that are not covered by the etch mask material portion 63 (such as a patterned photoresist material portion) can be removed by performing a hard mask etch process. The hard mask etch process may comprise an anisotropic etch process such as a reactive ion etch process. The anisotropic etch process can etch unmasked portions of the sacrificial planarization material layer 61 and the hard mask layer 67L selectively to the materials of the contact-level dielectric layer 70 and the sacrificial spacer liners 44. For example, if the hard mask layer 67L may comprise silicon nitride, and the anisotropic etch process may comprise a reactive ion etch process that employs CF₄/CHF₃, SF₆/O₂, or Cl₂/HBr/O₂.

Remaining portions of the hard mask layer 67L within each unit area UA after the hard mask etch process comprises at least one hard mask plate 67. In one embodiment, the at least one hard mask plate 67 comprises a plurality of hard mask plates 67. In one embodiment, a row of hard mask openings 69 (such as a row of the second hard mask opening 692, the first hard mask opening 691, and the third hard mask opening 693) may be arranged along the first horizontal direction hd1, and the etch mask material portion 63 (such as a patterned photoresist material portion) may partially cover each hard mask opening (691, 692, 693) within the row of hard mask openings (691, 692, 693) without covering an entirety of any hard mask opening (691, 692, 693) within the row of hard mask openings (691, 692, 693). In this case, a first hard mask plate 67 may be formed between a first via cavity 78 which is located within the area of the first hard mask opening 691 as formed at the processing steps of FIG. 3A-3D and a second via cavity 75 which is located within the area of the second hard mask opening 692 as formed at the processing steps of FIG. 3A-3D. Further, a second hard mask plate 67 may be formed between the first via cavity 78 which is located within the area of the first hard mask opening 691 as formed at the processing steps of FIG. 3A-3D and a third via cavity 75 which is located within the area of the third hard mask opening 693 as formed at the processing steps of FIG. 3A-3D. In this case, the at least one hard mask plate 67 comprises a plurality of hard mask plates 67 that are laterally spaced apart along the first horizontal direction hd1. In summary, the hard mask etch process patterns the hard mask layer 67L into at least one discrete hard mask plate 67.

In one embodiment, the at least one discrete hard mask plate 67 comprises two discrete hard mask plates 67 that are laterally spaced from each other along the first horizontal direction hd1. The etch mask material portion 63 within each unit area UA may be subsequently removed, for example, by performing an ashing process.

According to an aspect of the present disclosure, each hard mask plate 67 may have a sub-lithographic dimension HW along the first horizontal direction hd1. A first void 78′ may be provided in a center region within the first via cavity, i.e., the drain contact via cavity 78. A second void 75′ may be provided in a center region within the second via cavity, i.e., the first gate contact via cavity 75. A third void 75′ may be provided in a center region within the third via cavity, i.e., the second gate contact via cavity 75. A fourth void 72′ may be formed in a center region within the fourth via cavity, i.e., the first source contact via cavity 72. A fifth void 72′ may be formed in a center region within the fifth via cavity, i.e., the second source contact via cavity 72.

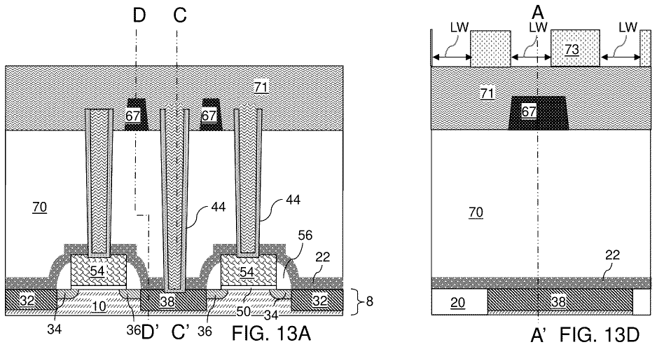

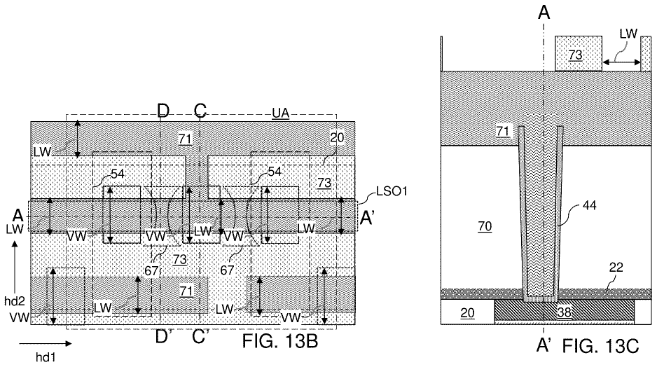

Referring to FIGS. 13A, 13B, 13C, and 13D, a self-planarizing material layer 71 can be formed over the contact-level dielectric layer 70 and the hard mask plates 67. The self-planarizing material layer 71 can be formed employing a self-planarization process such as spin coating. The self-planarizing material layer 71 comprises a bottom anti-reflective coating (BARC) material or a planarizing underlayer material such as spin-on-carbon (SOC) or an organic planarization layer (OPL). The self-planarizing material layer 71 can be formed in center regions of the via cavities (78, 75, 72) on the sacrificial spacer liners 44, on the top surface of the contact-level dielectric layer 70, and over the at least one discrete hard mask plate 67 that is provided within each unit area UA. Thus, the top surface of the self-planarizing material layer 71 can be planar or substantially planar, and reduces surface topography relative to the top surfaces of underlying structures.

A blanket photoresist layer can be applied over the self-planarizing material layer 71, and can be lithographically patterned to provide a patterned photoresist layer 73. Specifically, the pattern of the metal lines to be subsequently formed is an intersection of the pattern of the openings in the patterned photoresist layer 73 and the complementary pattern of openings in the hard mask plates 67. A complementary pattern for a reference pattern refers to a smallest pattern that can combine with the reference pattern to cover an entire area. In other words, the pattern of the metal lines to be subsequently formed corresponds to the pattern of the area of the openings through the patterned photoresist layer 73 that does not overlap with the areas of the hard mask plates 67. Thus, subsequent formation of the metal lines is inhibited within the areas of the hard mask plates 67 (i.e., the metal lines are not formed within the areas of the hard mask plates 67). The patterned photoresist layer 73 includes openings containing a component pattern of metal lines to be subsequently formed.

In one embodiment, the pattern of the openings in the patterned photoresist layer 73 may comprise line-shaped openings having a uniform width along the second horizontal direction hd2. The uniform width of the line-shaped openings is herein referred to as a line width LW. In one embodiment, the line width LW may be less than the via width VW. In one embodiment, the line-shaped openings that laterally extend along the first horizontal direction hd1 may be laterally spaced apart from each other along the second horizontal direction hd2 with a uniform pitch, which equals the sum of the line width LW and a line spacing which equals the uniform distance between a neighboring pair of line-shaped openings that are laterally spaced from each other along the first horizontal direction. In one embodiment the line width LW and the line spacing may be critical dimensions for the lithographic patterning tool that patterns the patterned photoresist layer 73.

In one embodiment, the at least one hard mask plate 67 within each unit area UA may comprise two discrete hard mask plates 67 arranged along the first horizontal direction hd1. As shown in FIG. 13B, the at least one hard mask plate 67 within each unit area UA may comprise a plurality of hard mask plates 67 arranged along the first horizontal direction hd1, and the patterned photoresist layer 73 comprises a first line-shaped opening LSO1 that laterally extends along the first horizontal direction hd1 and overlaps with each of the plurality (e.g., two) of hard mask plates 67 in a plan view.

In one embodiment, the first line-shaped opening LSO1 has an areal overlap with a center region of a shape of the first hard mask opening 691 and does not overlap with a pair of peripheral areal segments of the shape of the first hard mask opening 691 as formed at the processing steps of FIG. 3A-3D. The pair of peripheral areal segments are laterally spaced from each other along the second horizontal direction hd2 by the line width LW.

The first line-shaped opening LSO1 has a uniform line width LW along a second horizontal direction hd2 that is perpendicular to the first horizontal direction hd1. In one embodiment, the patterned photoresist layer 73 comprises an H-shaped line opening that includes a first lengthwise line-shaped opening segment that laterally extends along the first horizontal direction hd1, a second lengthwise line-shaped opening segment that laterally extends along the first horizontal direction hd1 and laterally offset from the first lengthwise line-shaped opening segment along the second horizontal direction hd2, and a widthwise line-shaped opening segment that laterally extends along a second horizontal direction hd2 and connects the first lengthwise line-shaped opening segment and the second lengthwise line-shaped opening segment.

In one embodiment, the first lengthwise line-shaped opening segment has an areal overlap with the two discrete hard mask plates 67 that are laterally spaced from each other along a first horizontal direction hd1. In one embodiment, the first via cavity (such as a drain contact via cavity 78) has a via width VW along the second horizontal direction hd2, and an area bounded by an upper periphery of the first via cavity (such as a drain contact via cavity 78) in the plan view comprises a pair of peripheral areal segments that do not have any areal overlap with the first line-shaped opening LSO1 in the plan view.

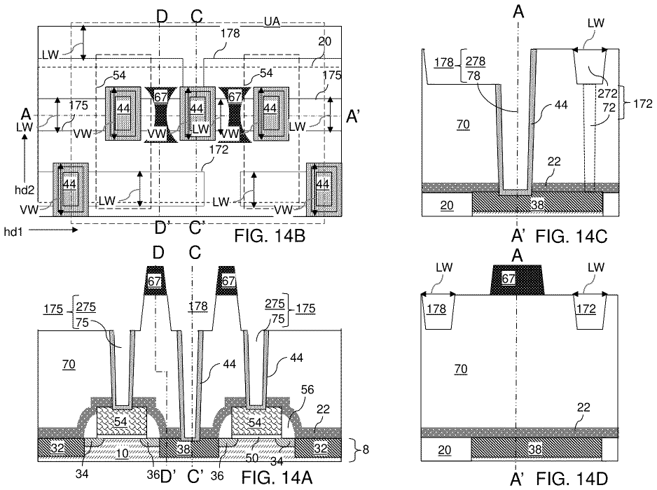

Referring to FIGS. 14A, 14B, 14C, and 14D, an anisotropic line etch process may be performed to transfer the pattern in the patterned photoresist layer 73 through the self-planarizing material layer 71 and into an upper portion of the contact-level dielectric layer 70 while employing the hard mask plates 67 as an additional etch mask pattern. Thus, the self-planarizing material layer 71 can be removed within all areas that are not masked by the patterned photoresist layer 73. The upper portion of the contact-level dielectric layer 70 can be removed within all areas that are not masked by the patterned photoresist layer 73 or the hard mask plates 67. Line cavities are formed in the volumes from which the material of the contact-level dielectric layer 70 is removed. The patterned photoresist layer 73 can be subsequently removed, for example, by ashing.

Subsequently, a selective removal process, such as an ashing process, can be performed to remove any remaining portion of the self-planarizing material layer 71. If residual portions of the self-planarizing material layer 71 are present in center regions of the via cavities (78, 75, 72) on the sacrificial spacer liners 44, a selective removal process, such as an ashing process, can be performed to remove any remaining portion of the self-planarizing material layer 71.

Integrated line-and-via cavities (178, 175, 172) can be formed by performing an anisotropic line etch process that employs a combination of a patterned photoresist layer 73 and the at least one (e.g., two) discrete hard mask plate 67 as a line etch mask. In one embodiment, the integrated line-and-via cavities (178, 175, 172) may comprise a drain-side integrated line-and-via cavity 178 comprising a drain-side line cavity 278 and a drain contact via cavity 78, a first gate-side integrated line-and-via cavity 175 comprising a first gate-side line cavity 275 and a first gate contact via cavity 75, a second gate-side integrated line-and-via cavity 175 comprising a second gate-side line cavity 275 and a second gate contact via cavity 75, a first source-side integrated line-and-via cavity 172 comprising a first source-side line cavity 272 and a first source-side via cavity 72, and a second source-side integrated line-and-via cavity 172 comprising a second source-side line cavity 272 and a second source-side via cavity 72.

The integrated line-and-via cavities (178, 175, 172) include all volumes of the via cavities (78, 75, 72) and volumes of line cavities (278, 275, 272) that are formed by removal of upper portions of the contact-level dielectric layer 70 by the anisotropic line etch process. In one embodiment, the via cavities (78, 75, 72) comprise a first via cavity (such as a drain contact via cavity 78) that is formed underneath the first hard mask opening 691, and the line cavities (278, 275, 272) comprise a first line cavity (e.g., 278) that is formed underneath the first line-shaped opening LSO1 in the patterned photoresist layer 73. The combination of the first line cavity 278 and the first via cavity 78 constitutes a first integrated line-and-via cavity, which is the drain-side integrated line-and-via cavity 178.

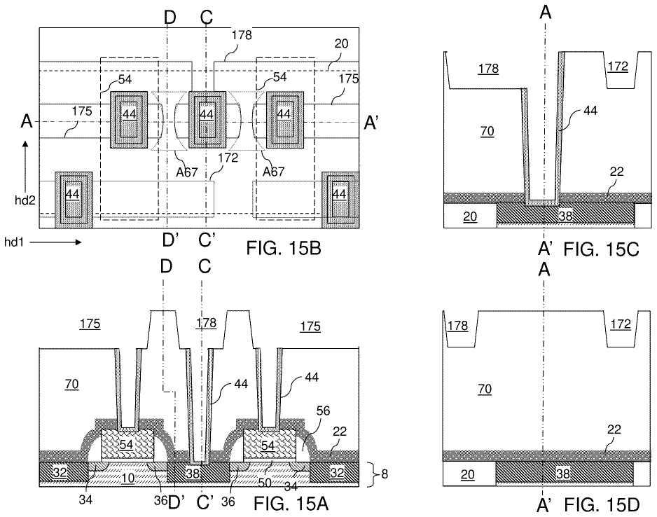

Referring to FIGS. 15A, 15B, 15C, and 15D, the hard mask plates 67 can be removed selectively to the materials of the contact-level dielectric layer 70 and the sacrificial spacer liners 44. For example, if the hard mask plates 67 comprise silicon nitride, a wet etch process employing hot phosphoric acid may be performed to remove the hard mask plates 67. The areas that were previously occupied by the two discrete hard mask plates 67 are denoted as “A67” in FIG. 15B.

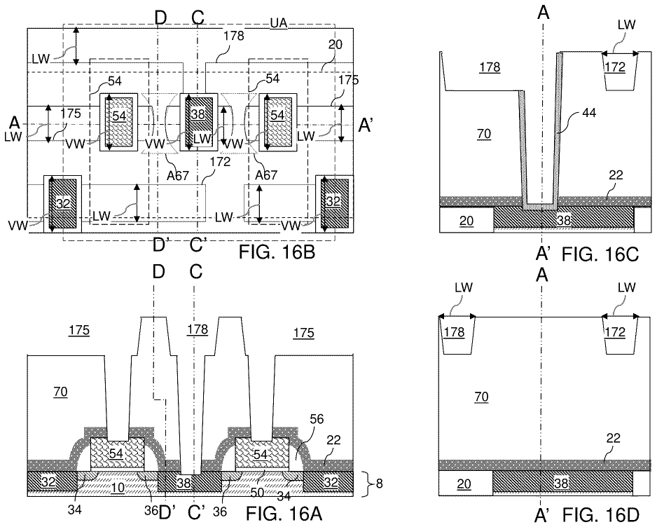

Referring to FIGS. 16A, 16B, 16C, and 16D, the sacrificial spacer liners 44 may be removed selectively to the materials of the contact-level dielectric layer 70 and the dielectric capping liner 22. For example, a wet etch process employing dilute hydrofluoric acid may be performed to remove the material of the sacrificial spacer liners 44 at a higher etch rate than the materials of the contact-level dielectric layer 70 and the dielectric capping liner 22. Generally, upon removal of the sacrificial spacer liners 44, volumes of the integrated line-and-via cavities (178, 175, 172) increase by volumes of the sacrificial spacer liners 44 that are removed.

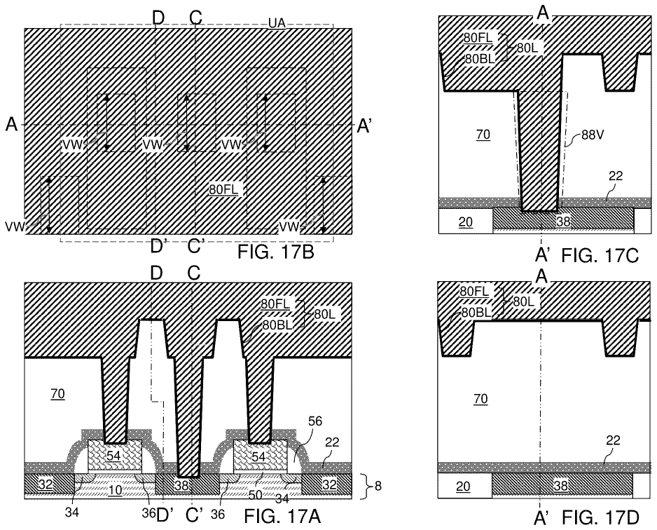

Referring to FIGS. 17A, 17B, 17C, and 17D, a metallic barrier liner layer 80BL and a metal fill material layer 80FL can be deposited in the integrated line-and-via cavities (178, 175, 172). The metallic barrier liner layer 80BL comprises a conductive metallic diffusion barrier material, such as TiN, TaN, WN, or MoN. The metallic barrier liner layer 80BL may be deposited by physical vapor deposition or chemical vapor deposition. The thickness of the metallic barrier liner layer 80BL may be in a range from 3 nm to 30 nm, although lesser and greater thicknesses may also be employed. The metal fill material layer 80FL comprises a metal, such as Cu, W, Ti, Ta, Mo, Ru, etc. The metal fill material layer 80FL may be deposited by electroplating or chemical vapor deposition.

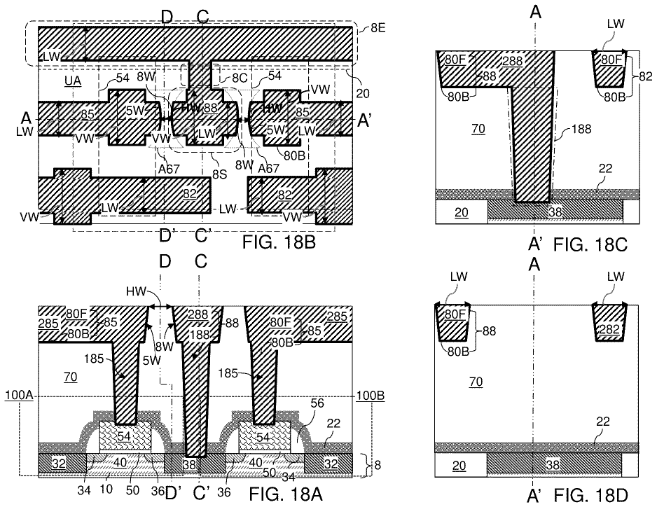

Referring to FIGS. 18A, 18B, 18C, and 18D, a chemical mechanical polishing process may be performed to remove excess portions of the metallic barrier liner layer 80BL and the metal fill material layer 80FL that are located above the horizontal plane including the topmost surface of the contact-level dielectric layer 70. Remaining portions of the metallic barrier liner layer 80BL and the metal fill material layer 80FL comprise metal interconnect structures. The metal interconnect structures are formed within the integrated line-and-via cavities (178, 175, 172). As such, the metal interconnect structures may comprise integrated line-and-via structures (88, 85, 82).

In one embodiment, the metal interconnect structures comprise a first integrated line-and-via structure (such as an integrated drain contact line-and-via structure 88) that is formed in the first integrated line-and-via cavity 178; a second integrated line-and-via structure (such as a first integrated gate contact line-and-via structure 85) that is formed in a second integrated line-and-via cavity 175; a third integrated line-and-via structure (such as a second integrated gate contact line-and-via structure 85) that is formed in a third integrated line-and-via cavity 175; a fourth integrated line-and-via structure (such as a first integrated source contact via structure 82) that is formed in a fourth integrated line-and-via cavity 172; and a fifth integrated line-and-via structure (such as an integrated source line-and-via structure 82) that is formed in a fifth integrated line-and-via cavity 172. In one embodiment, the fifth integrated line-and-via structure may comprise a power line-and-via structure 82 that provides electric power to the first and second field effect transistors (100A, 100B)

Each of the integrated line-and-via structures (88, 85, 82) comprises a combination of a respective metallic barrier liner 80B and a metal fill material portion 80F. Each metallic barrier liner 80B is a patterned portion of the metallic barrier liner layer 80BL. Each metal fill material portion 80F is a patterned portion of the metal fill material layer 80FL.

In one embodiment, the first integrated line-and-via structure (such as an integrated drain contact line-and-via structure 88) comprises a first via portion that is formed within the first via cavity (such as a drain contact via cavity 78) and a first metal line portion that is formed within the first line cavity. In one embodiment, the first via portion comprises a pair of via sidewalls that laterally extend along the first horizontal direction hd1 and having top edges that are laterally spaced apart from each other along the second horizontal direction hd2 by the via width VW. In one embodiment, the first metal line portion comprises a pair of line sidewalls that laterally extend along the first horizontal direction hd1 and having top edges that are laterally spaced apart from each other along the second horizontal direction hd2 by the line width LW.

In one embodiment, the second integrated line-and-via structure (such as a first integrated gate contact line-and-via structure 85) comprises a second via portion that is formed within the second via cavity (such as a first gate contact via cavity 75) and a second metal line portion that is formed within the second line cavity. In one embodiment, the second via portion comprises a pair of via sidewalls that laterally extend along the first horizontal direction hd1 and having top edges that are laterally spaced apart from each other along the second horizontal direction hd2 by the via width VW. In one embodiment, the second metal line portion comprises a pair of line sidewalls that laterally extend along the first horizontal direction hd1 and having top edges that are laterally spaced apart from each other along the second horizontal direction hd2 by the line width LW.

In one embodiment, the third integrated line-and-via structure (such as a second integrated gate contact line-and-via structure 85) comprises a third via portion that is formed within the third via cavity (such as a second gate contact via cavity 75) and a third metal line portion that is formed within the third line cavity. In one embodiment, the third via portion comprises a pair of via sidewalls that laterally extend along the first horizontal direction hd1 and having top edges that are laterally spaced apart from each other along the second horizontal direction hd2 by the via width VW. In one embodiment, the third metal line portion comprises a pair of line sidewalls that laterally extend along the first horizontal direction hd1 and having top edges that are laterally spaced apart from each other along the second horizontal direction hd2 by the line width LW.

In one embodiment, the fourth integrated line-and-via structure (such as a first integrated source contact line-and-via structure 82) comprises a fourth via portion that is formed within the fourth via cavity (such as a first source contact via cavity 72) and a fourth metal line portion that is formed within the fourth line cavity. In one embodiment, the fourth via portion comprises a pair of via sidewalls that laterally extend along the first horizontal direction hd1 and having top edges that are laterally spaced apart from each other along the second horizontal direction hd2 by the via width VW. In one embodiment, the fourth metal line portion comprises a pair of line sidewalls that laterally extend along the first horizontal direction hd1 and having top edges that are laterally spaced apart from each other along the second horizontal direction hd2 by the line width LW.

In one embodiment, the fifth integrated line-and-via structure (such as a second integrated source contact line-and-via structure 82) comprises a fifth via portion that is formed within the fifth via cavity (such as a second source contact via cavity 72) and a fifth metal line portion that is formed within the fifth line cavity. In one embodiment, the fifth via portion comprises a pair of via sidewalls that laterally extend along the first horizontal direction hd1 and having top edges that are laterally spaced apart from each other along the second horizontal direction hd2 by the via width VW. In one embodiment, the fifth metal line portion comprises a pair of line sidewalls that laterally extend along the first horizontal direction hd1 and having top edges that are laterally spaced apart from each other along the second horizontal direction hd2 by the line width LW.

According to an aspect of the present disclosure shown in FIG. 18B, the metal interconnect structures comprise: a first metal interconnect structure (such as the integrated drain contact line-and-via structure 88) comprising a stub portion 8S that is formed between areas A67 of the two discrete hard mask plates 67 in the plan view; a second metal interconnect structure (such as the first integrated gate contact line-and-via structure 85) that is formed on a first side of the areas A67 two discrete hard mask plates 67 along the first horizontal direction hd1 in the plan view; and a third metal interconnect structure (such as the second integrated gate contact line-and-via structure 85) that is formed on a second side of the areas A67 two discrete hard mask plate 67 along the first horizontal direction hd1 in the plan view, the second side being an opposite of the first side.

In one embodiment, the first metal interconnect structure (such as the integrated drain contact line-and-via structure 88) further comprises: an elongated line portion 8E that laterally extends along the first horizontal direction hd1 and is laterally offset from the areas A67 of the two discrete hard mask plates 67 along a second horizontal direction hd2 that is perpendicular to the first horizontal direction hd1; and a connection line portion 8C that laterally extends along the second horizontal direction hd2 and connecting the stub portion 8S and the elongated line portion 8E.

As shown in FIG. 18B, the stub portion 8S has a first convex sidewall 8W with low curvature (low convexity) that extends substantially along the second horizontal direction hd2 and that is separated from a second convex sidewall 5W of the first integrated gate contact line-and-via structure 85 by a sub-lithographic width HW along the first horizontal direction hd1. The second convex sidewall 5W of the first integrated gate contact line-and-via structure 85 protrudes past the edge of the first gate electrode 54 in plan view by a relatively small distance, which increases device density. The line portions (288, 285, 282) of the metal interconnect structures (88, 85, 82) are wider at their top than at their bottom. This increases the contact area for overlying interconnects. The area A67 of the discrete hard mask plate 67 that separates the first convex sidewall 8W of the stub portion 8S from the second convex sidewall 5W is bow-tie shaped, having concave sidewalls, a narrow middle portion having the sub-lithographic width HW and wider end portions on either side of the middle portion.

Referring to FIG. 18A-18D, a field effect transistor 100A comprises a semiconductor source region 32; a semiconductor drain region 38; a semiconductor channel region 40 located between the semiconductor source region 32 and the semiconductor drain region 38; a gate dielectric layer 50 located over the semiconductor channel region 40; and a gate electrode 54 located over the gate dielectric layer 50. A contact-level dielectric layer 70 is located over the gate electrode 54. A drain integrated line-and-via structure 88 is embedded in the contact-level dielectric layer 70, and comprises a first via portion 188 that contacts the semiconductor drain region 38 and a first line portion 288 overlying the first via portion 188. A gate integrated line-and-via structure 85 is also embedded in the contact-level dielectric layer 70, and comprises a second via portion 185 that contacts the gate electrode 54 and a second line portion 285 overlying the second via portion 185. The first line portion 288 comprises: an elongated line portion 8E that laterally extends along a first horizontal direction hd1 and is laterally offset from the first via portion 188 and the second via portion 185 along a second horizontal direction hd2 that is perpendicular to the first horizontal direction hd1; a stub portion 8S that overlies the first via portion 188 and having a first convex sidewall 8W that extends substantially along the second horizontal direction hd2; and a connection line portion 8C that laterally extends along the second horizontal direction hd2 and connecting the stub portion 8S and the elongated line portion 8E. The second line portion 285 comprises a second convex sidewall 5W that extends substantially along the second horizontal direction hd2 and faces the first convex sidewall 8W; and the first and the second line portions (288, 285) are wider at their top than at their bottom.

Thus, the embodiments of the present disclosure provide field effect transistors (100A, 100B) that have a sub-lithographic spacing between the line portions (278, 275) of the respective drain and gate line-and-via structures (178, 175). This increases the device density. Furthermore, by using the sacrificial discrete hard mask plates 67, the process cost may be reduced.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

1. A method of forming a device structure, comprising:
forming a contact-level dielectric layer over a semiconductor device;
forming a hard mask layer containing hard mask openings over top surface of the contact-level dielectric layer;
forming via cavities through the contact-level dielectric layer by performing an anisotropic via etch process that employs a hard mask layer as a via etch mask;
forming sacrificial spacer liners in peripheral regions of the via cavities;
patterning the hard mask layer into at least one discrete hard mask plate;
forming integrated line-and-via cavities by performing an anisotropic line etch process that employs a combination of a patterned photoresist layer and the at least one discrete hard mask plate as a line etch mask, wherein the integrated line-and-via cavities include all volumes of the via cavities and volumes of line cavities that are formed by removal of upper portions of the contact-level dielectric layer by the anisotropic line etch process;
removing the patterned photoresist layer, the at least one discrete hard mask plate, and the sacrificial spacer liners, such that volumes of the integrated line-and-via cavities increase by volumes of the removed sacrificial spacer liners; and
forming metal interconnect structures within the integrated line-and-via cavities.

2. The method of claim 1, wherein:
the at least one discrete hard mask plate comprises two discrete hard mask plates that are laterally spaced from each other along a first horizontal direction; and
the patterned photoresist layer comprises a first line-shaped opening that laterally extends along the first horizontal direction and overlaps with the two discrete hard mask plates in a plan view.

3. The method of claim 2, wherein:
the first line-shaped opening has a uniform line width along a second horizontal direction that is perpendicular to the first horizontal direction;
the hard mask openings comprise a first hard mask opening having a via width along the second horizontal direction; and
the first line-shaped opening has an areal overlap with a center region of a shape of the first hard mask opening and does not overlap with a pair of peripheral areal segments of the shape of the first hard mask opening, the pair of peripheral areal segments being laterally spaced from each other along the second horizontal direction by the line width.

4. The method of claim 3, wherein:
the via cavities comprise a first via cavity that is formed underneath the first hard mask opening;
the line cavities comprise a first line cavity that is formed underneath the first line-shaped opening in the patterned photoresist layer; and
the metal interconnect structures comprise a first integrated line-and-via structure comprising a first via portion that is formed within the first via cavity and a first metal line portion that is formed within the first line cavity.

5. The method of claim 4, wherein:
the first via portion comprises a pair of via sidewalls that laterally extend along the first horizontal direction and having top edges that are laterally spaced apart from each other along the second horizontal direction by the via width; and
the first metal line portion comprises a pair of line sidewalls that laterally extend along the first horizontal direction and having top edges that are laterally spaced apart from each other along the second horizontal direction.

6. The method of claim 4, wherein the metal interconnect structures further comprise:
a stub portion of the first metal line portion that is formed between areas of the two discrete hard mask plates in the plan view;
a second metal interconnect structure that is formed on a first side of the areas of the two discrete hard mask plates along the first horizontal direction in the plan view; and
a third metal interconnect structure that is formed on a second side of the areas of the two discrete hard mask plate along the first horizontal direction in the plan view, the second side being an opposite of the first side.

7. The method of claim 6, wherein the first metal line portion further comprises:
an elongated line portion that laterally extends along the first horizontal direction and is laterally offset from the areas of the two discrete hard mask plates along a second horizontal direction that is perpendicular to the first horizontal direction; and
a connection line portion that laterally extends along the second horizontal direction and connecting the stub portion and the elongated line portion.

8. The method of claim 2, wherein:
the hard mask openings comprise a first hard mask opening having a first peripheral edge; and
the hard mask layer is patterned such that each of the two discrete hard mask plates comprises a respective edge segment of the first peripheral edge.

9. The method of claim 8, wherein:
the via cavities comprise a first via cavity that is formed underneath the first hard mask opening; and
the first line-shaped opening has a partial areal overlap with the first via cavity in the plan view.

10. The method of claim 9, wherein:
the hard mask openings further comprise a second hard mask opening having a second peripheral edge and a third hard mask opening having a third peripheral edge;
the hard mask layer is patterned such that one of the two discrete hard mask plates comprises an edge segment of the second peripheral edge and another of the two discrete hard mask plates comprises an edge segment of the third peripheral edge;
the via cavities further comprise a second via cavity that is formed underneath the second hard mask opening, and a third via cavity that is formed underneath the third hard mask opening;
the first line-shaped opening has areal overlaps with the second via cavity and with the third via cavity in the plan view;
the semiconductor device comprises a pair of field effect transistors having a common drain region, a first gate electrode, and a second gate electrode;
the first via cavity vertically extends down to a top surface segment of the common drain region;
the second via cavity vertically extends down to a top surface segment of the first gate electrode; and
the third via cavity vertically extends down to a top surface segment of the second gate electrode.

11. The method of claim 9, wherein:
the first line-shaped opening has a line width along a second horizontal direction that is perpendicular to the first horizontal direction;
the first via cavity has a via width along the second horizontal direction; and
an area bounded by an upper periphery of the first via cavity in the plan view comprises a pair of peripheral areal segments that do not have any areal overlap with the first line-shaped opening in the plan view.

12. The method of claim 1, wherein:
the at least one discrete hard mask plate comprises two discrete hard mask plates that are laterally spaced from each other along a first horizontal direction;
the patterned photoresist layer comprises an H-shaped line opening that includes a first lengthwise line-shaped opening segment that laterally extends along the first horizontal direction, a second lengthwise line-shaped opening segment that laterally extends along the first horizontal direction and laterally offset from the first lengthwise line-shaped opening segment, and a widthwise line-shaped opening segment that laterally extends along a second horizontal direction and connecting the first lengthwise line-shaped opening segment and the second lengthwise line-shaped opening segment; and
the first lengthwise line-shaped opening segment has an areal overlap with the two discrete hard mask plates.

13. The method of claim 1, further comprising:
forming an etch mask material portion over the hard mask layer; and
removing portions of the hard mask layer that are not covered by the etch mask material portion by performing a hard mask etch process, wherein remaining portions of the hard mask layer after the hard mask etch process comprises the at least one hard mask plate.

14. The method of claim 13, wherein:
a row of hard mask openings of the hard mask openings is arranged along a first horizontal direction;
the etch mask material portion partially covers each hard mask opening within the row of hard mask openings without covering an entirety of any hard mask opening within the row of hard mask openings;
the at least one hard mask plate comprises a plurality of hard mask plates that are laterally spaced apart along the first horizontal direction; and
the patterned photoresist layer comprises a first line-shaped opening that laterally extends along the first horizontal direction and overlaps with each of the plurality of hard mask plates in a plan view.

15. The method of claim 1, wherein the sacrificial spacer liners are formed by:
conformally depositing a sacrificial spacer liner layer in the peripheral regions of the via cavities and over the top surface of the contact-level dielectric layer;
forming sacrificial etch stop pillars in center regions of the via cavities by depositing and vertically recessing a sacrificial etch stop material; and
removing portions of the sacrificial spacer liner layer that are not masked by the sacrificial etch stop pillars.

16. The method of claim 1, further comprising:
forming a self-planarizing material layer in center regions of the via cavities on the sacrificial spacer liners, on the top surface of the contact-level dielectric layer, and over the at least one discrete hard mask plate; and
removing the self-planarizing material layer during formation of the integrated line-and-via cavities.

17. The method of claim 1, further comprising isotropically recessing the hard mask layer selectively to materials of the contact-level dielectric layer and the sacrificial spacer liners after formation of the sacrificial spacer liners.

18. A field effect transistor, comprising:
a semiconductor source region;
a semiconductor drain region;
a semiconductor channel region located between the semiconductor source region and the semiconductor drain region;
a gate dielectric layer located over the semiconductor channel region;
a gate electrode located over the gate dielectric layer;
a contact-level dielectric layer located over the gate electrode;
a drain integrated line-and-via structure embedded in the contact-level dielectric layer, and comprising a first via portion that contacts the semiconductor drain region and a first line portion overlying the first via portion; and
a gate integrated line-and-via structure embedded in the contact-level dielectric layer, and comprising a second via portion that contacts the gate electrode and a second line portion overlying the second via portion,
wherein:
the first line portion comprises:
an elongated line portion that laterally extends along a first horizontal direction and is laterally offset from the first and second via portions along a second horizontal direction that is perpendicular to the first horizontal direction;
a stub portion that overlies the first via portion and having a first convex sidewall that extends substantially along the second horizontal direction; and
a connection line portion that laterally extends along the second horizontal direction and connecting the stub portion and the elongated line portion;
the second line portion comprises a second convex sidewall that extends substantially along the second horizontal direction and faces the first convex sidewall; and
the first and the second line portions are wider at their top than at their bottom.

19. The field effect transistor of claim 18, wherein:
an area that separates the first convex sidewall from the second convex sidewall is bow-tie shaped, having concave sidewalls, a narrow middle portion and wider end portions on either side of the middle portion; and
the second convex sidewall protrudes past the edge of the gate electrode in plan view.

20. The field effect transistor of claim 18, wherein the semiconductor drain region is shared with a second field effect transistor having a second semiconductor source region, and second semiconductor channel region located between the second semiconductor source region and the semiconductor drain region, a second gate dielectric layer located over the second semiconductor channel region; a second gate electrode located over the second gate dielectric layer and under the contact-level dielectric layer.
